(19) United States
(12) Patent Application Publication
(10) Pub. No.: US 2022/0397813 A1
(43) Pub. Date: Dec. 15, 2022

(54) PROJECTION DEVICE

(71) Applicant: Qisda Corporation, Taoyuan City (TW)

(72) Inventors: Tsung-Hsien YANG, Taoyuan City (TW); Yu-Ting LIOU, Taoyuan City (TW)

(73) Assignee: Qisda Corporation, Taoyuan City (TW)

(21) Appl. No.: 17/729,072

(22) Filed: Apr. 26, 2022

(30) Foreign Application Priority Data
Jun. 10, 2021 (CN) 202110647028.4

(51) Int. Cl. G03B 21/16; H05K 7/20

(52) U.S. Cl. CPC G03B 21/16; H05K 7/20136

(57) ABSTRACT

A projection device configured to project an image in a projection direction is provided. The projection device includes a housing and a projection module. The housing has an air inlet and an air outlet, wherein the air inlet, the air outlet and the projection direction are in the same direction. The projection module is disposed inside the housing. The projection direction and a direction of gravity are in the same direction.

### PROJECTION DEVICE

This application claims the benefit of People's Republic of China application Serial No. 202110647028.4, filed on Jun. 10, 2021, the subject matter of which is incorporated herein by reference.

### BACKGROUND OF THE INVENTION

### Field of the Invention

The invention relates in general to a device, and more particularly to a projection device.

### Description of the Related Art

A conventional projection device includes a housing, an air outlet and an air inlet, wherein the air outlet and the air inlet are arranged on lateral plate of a housing. Such structure normally is suitable to be placed on a desktop and limits the arrangement direction of the projection device. Therefore, it has become a prominent task for the industries to resolve the above problems.

### SUMMARY OF THE INVENTION

The invention is directed to a projection device capable of resolving the problems encountered in the prior art.

According to one embodiment of the present invention, a projection device is provided. The projection device is configured to project an image in a projection direction. The projection device includes a housing and a projection module. The housing has an air inlet and an air outlet, wherein the air inlet, the air outlet and the projection direction are in the same direction. The projection module is disposed inside the housing. The projection direction and a direction of gravity are in the same direction.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of a projection device according to an embodiment of the present invention.

FIG. 2 is a schematic diagram of the projection device of FIG. 1 along a direction 2-2′.

FIG. 3 is a schematic diagram of a movement path of a hole on the casing of FIG. 2 corresponding to an air inlet of the second fan.

FIG. 4 is a schematic diagram of a projection device according to another embodiment of the present invention.

### DETAILED DESCRIPTION OF THE INVENTION

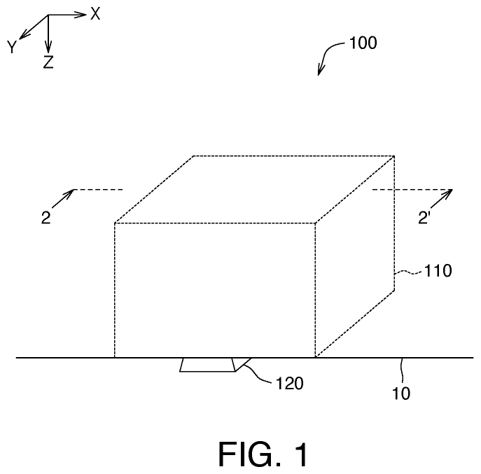

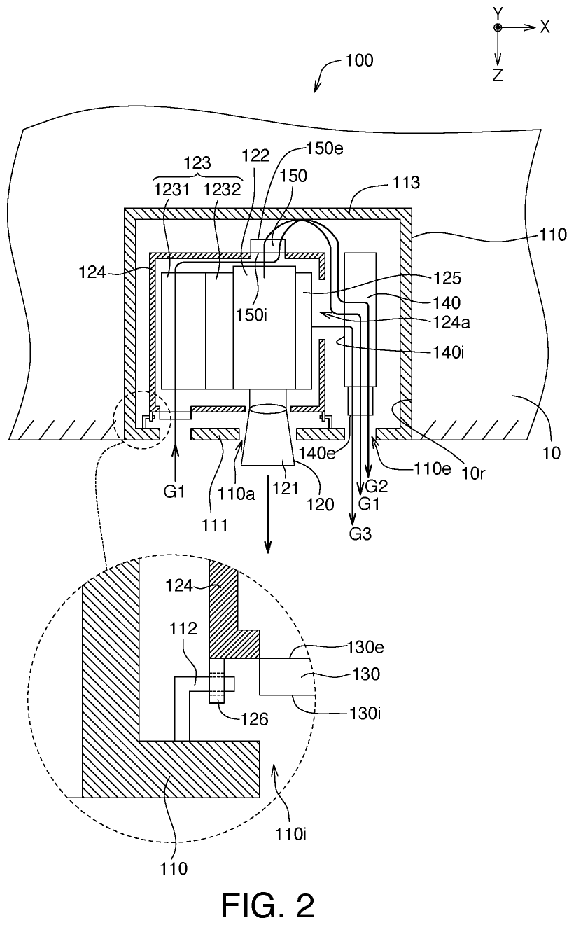

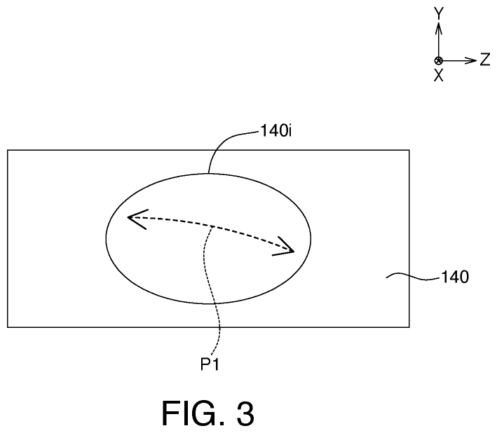

Refer to FIGS. 1 to 3. FIG. 1 is a schematic diagram of a projection device 100 according to an embodiment of the present invention. FIG. 2 is a schematic diagram of the projection device 100 of FIG. 1 along a direction 2-2′. FIG. 3 is a schematic diagram of a movement path P1 of a hole 124a on the casing 124 of FIG. 2 opposite to an air inlet 140i of the second fan 140.

The projection device 100 is configured to project an image (not illustrated) in a projection direction Z. The projection device 100 includes a housing 110, a projection module 120, a first fan 130, a second fan 140 and a third fan 150. The X-axis, Y-axis and Z-axis of the diagrams are substantially perpendicular to each other.

In an embodiment, the housing 110 has an air inlet (the first air inlet) 110i and an air outlet (the first air outlet) 110e, wherein the air inlet 110i, the air outlet 110e and the projection direction Z substantially are in the same direction. The projection module 120 at least is partly disposed inside the housing 110. The projection direction Z and the direction of gravity substantially are in the same direction, such as are facing downward. Thus, the projection device 100 can project an image towards a ground, a desktop, a floor or a lower board.

As indicated in FIG. 2, the air outlet 110e and the air inlet 110i are substantially coplanar. In another embodiment, the air outlet 110e and the air inlet 110i can have a level difference in the direction of gravity, that is, a level difference is formed between the air outlet 110e and the air inlet 110i.

As indicated in FIG. 2, the projection device 100 can be embedded in the recessed portion 10r of the carrier 10. For example, the housing 110 of the projection device 100 can be fixed in the recessed portion 10r. Depending on the types of the carrier 10, the recessed portion 10r can be a via hole or a blind hole. The direction of gravity passes through the recessed portion 10r. The carrier 10 can be the ceiling of a building or the casing of a transportation. The air inlet 110i and the air outlet 110e are exposed from the recessed portion 10r, so that airflow can enter the projection device via the air inlet 110i and exit via the air outlet 110e.

As indicated in FIG. 2, the housing 110 has a lateral plate 111. The lateral plate 111 has the air outlet 110e and the air inlet 110i and an opening 110a. The projection module 120 includes a projection lens 121 at least partly disposed inside the housing 110. The projection lens 121 is protruded relative to the opening 110a for the convenience of operation. For example, the angle of the projection lens 121 relative to the housing 110 can be adjusted through the protrusion of the projection lens 121 relative to the opening 110a.

As indicated in FIG. 2, the projection module 120 further includes an optical machine 122, a dissipation module 123, a casing 124 and a power control unit 125. Each of the projection lens 121, the optical machine 122, the dissipation module 123 and the power control unit 125 at least is partly disposed inside the casing 124. The projection lens 121, the optical machine 122, the dissipation module 123 and the power control unit 125 can be linked with the casing 124. Thus, when the casing 124 rotates relative to the housing 110, the projection lens 121, the optical machine 122, the dissipation module 123 and the power control unit 125 also rotate with the housing 110. Since the optical machine 122 can rotate with the housing 110, the angle and/or position of the projected image relative to the projection module 120 can be adjusted.

As indicated in FIG. 2, the dissipation module 123 is disposed adjacent to the optical machine 122 and can transfer the heat of the optical machine 122. The dissipation module 123 may include a heat sink 1231 and a heat conductor 1232. The heat conductor 1232 can transfer the heat to the heat sink 1231. In an embodiment, the heat conductor 1232 can be realized by a heat pipe which is corresponding to the first fan 130 in position, so that the first fan 130 can dissipate the heat off the heat sink 1231.

As indicated in FIG. 2, the casing 124 surrounds the optical machine 122, the dissipation module 123 and the power control unit 125 and therefore encloses the heat generated by these elements inside the casing 124. Thus, when the casing 124 moves relative to the housing 110, most of the heat is still controlled or limited within the space of the casing 124, so that the airflow inside the casing 124 can absorb most of the heat generated by these elements.

As indicated in FIG. 2, the casing 124 has a hole 124a. The power control unit 125 is disposed adjacent to the hole 124a. The heat generated by the power control unit 125 can be convected to the second fan 140 through the hole 124a, and the second fan 140 can dissipate the heat off the power control unit 125.

As indicated in FIG. 2, the projection module 120 is pivotally connected to the housing 110. Here, “pivotal connection” only means relative rotation between two elements and technical means of relative rotation is not specified. In an embodiment, the projection module 120 further includes at least one first pivotal element 126, and the housing 110 includes at least one second pivotal element 112, wherein the second pivotal element 112 is pivotally connected to the first pivotal element 126, so that the projection module 120 can move relative to the housing 110. In an embodiment, the second pivotal element 112 is extended in the X-axis, so that the projection module 120 can rotate around the X-axis relative to the housing 110.

As indicated in FIG. 2, the first fan 130 has an air inlet (the second air inlet) 130i and an air outlet 130e, the first fan 130 can drive the first airflow G1 to enter the projection device via the air inlet 130i and exit via the air outlet 130e. The position of the air inlet 130i corresponds to that of air inlet 110i, so that, the first fan 130 can force the first airflow G1 to enter the housing 110 to absorb the heat inside the projection device 100. The air outlet 130e is opposite to the heat sink 1231, so that the first airflow G1 discharged from the air outlet 130e can absorb the heat off the heat sink 1231.

As indicated in FIG. 2, the third fan 150 has an air inlet (the third air inlet) 150i and an air outlet (the third air outlet) 150e. The third fan 150 can drive the first airflow G1 to enter the projection device via the air inlet 150i and then exit via the air outlet 150e. Besides, the third fan 150 is disposed adjacent to the optical machine 122, so that the second airflow G2 can absorb the heat off the optical machine 122. The air inlet 150i faces (such as is opposite to) the optical machine 122, so that the second airflow G2 which absorbs the heat off the optical machine 122 can enter via the air inlet 150i and exit via the air outlet 150e. Moreover, the housing 110 has a lateral plate 113. The lateral plate 113 and the lateral plate 111 are two opposite lateral plates of the housing 110. The air outlet 150e faces (such as is opposite to) the lateral plate 113 of the housing 110, so that the airflow (the first airflow G1 and the second airflow G2) discharged from the air outlet 150e can be rebounded by the lateral plate 113 and then dissipated off the projection device 100 by the second fan 140. In another embodiment, a part of the heat generated by the power control unit 125 can also be dissipated off the projection device 100 through the second airflow G2 and/or the first airflow G1.

As indicated in FIG. 2, the second fan 140 has an air inlet 140i and an air outlet (the second air outlet) 140e. The second fan 140 can drive airflow (the first airflow G1, the second airflow G2 and the third airflow G3) to enter the projection device via the air inlet 140i and then exit via the air outlet 140e. The third airflow G3 can absorb the heat off the power control unit 125. The position of the air inlet 140i corresponds to that of the hole 124a on the casing 124, so that the third airflow G3 can enter the air inlet 140i via the hole 124a and then is dissipated off the projection device 100 via the air outlet 140e. Besides, the first airflow G1 and the second airflow G2 can enter the air inlet 140i and then are dissipated off the projection device 100 via the air outlet 140e. In another embodiment, a part of the heat generated by the optical machine 122 can also be dissipated off the projection device 100 through the third airflow G3 and/or the first airflow G1.

To summarize, the heat generated by any element of the projection device 100 can be dissipated off the projection device 100 through at least one of the first airflow G1, the second airflow G2 and the third airflow G3.

In the present embodiment as indicated in FIG. 2, the first fan 130 and the third fan 150 are disposed inside the projection module 120, so that the first fan 130 and the third fan 150 can be linked with the projection module 120. The second fan 140 is disposed inside the housing 110. The second fan 140 does not need to rotate with the projection module 120. Thus, when the projection module 120 rotates relative to the housing 110, the air outlet 140e of the second fan 140 still faces (such as is opposite to) the air outlet 110e.

As indicated in FIG. 3, when the projection module 120 rotates relative to the housing 110, the movement path P1 of the hole 124a on the casing 124 (the casing 124 and the hole 124a are illustrated in FIG. 2) corresponds to the air inlet 140i of the second fan 140. Thus, even when the projection module 120 rotates relative to the housing 110, the hole 124a on the casing 124 still faces the air inlet 140i of the fourth fan 140, so that the airflow (the first airflow G1, the second airflow G2 and the third airflow G3) is not affected by rotation and can continue to enter the air inlet 140i.

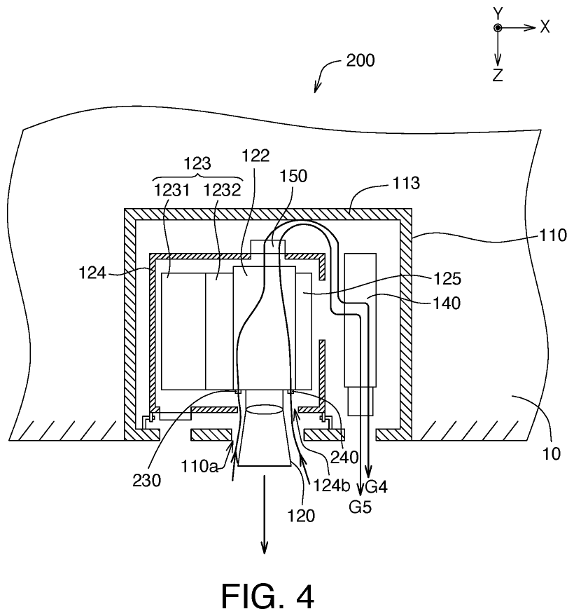

Referring to FIG. 4, a schematic diagram of a projection device 200 according to another embodiment of the present invention is shown. The projection device 200 is configured to project an image (not illustrated) in a projection direction Z. The projection device 200 includes a housing 110, a projection module 120, a first fan 130, a second fan 140, a third fan 150, a fourth fan 230 and a fifth fan 240. In the present invention embodiment, technical features of the projection device 200 are identical or similar to that of the projection device 100 except that the projection device 200 further includes a fourth fan 230 and a fifth fan 240.

As indicated in FIG. 4, the fourth fan 230 and the fifth fan 240 are disposed on the casing (unmarked) of the optical machine 122. For example, the casing of the optical machine 122 has at least one via hole (unmarked), through which the fourth fan 230 and the fifth fan 240 are disposed inside or outside the casing. The fourth fan 230 and the fifth fan 240 can drive airflow to enter the optical machine 122 to cool the optical machine 122. For example, under the forced convection of the fourth fan 230, the fourth airflow G4 sequentially passes through the opening 110a of the housing 110, the opening 124b of the casing 124, the fourth fan 230 and the optical machine 122. Then, the fourth airflow G4 is dissipated off the optical machine 122 by the third fan 150, rebounded by the lateral plate 113, and then is dissipated off the projection device 200 by the second fan 140. Similarly, under the forced convection of the fifth fan 240, the fifth airflow G5 sequentially passes through the opening 110a of the housing 110, the opening 124b of the casing 124, the fifth fan 240 and the optical machine 122. Then, the fifth airflow G5 is dissipated off the optical machine 122 by the third fan 150, rebounded from the lateral plate 113, and then is dissipated off the projection device 200 by the second fan 140.

In another embodiment, the projection device 200 can omit either one of the fourth fan 230 and the fifth fan 240.

Although it is not illustrated, under the forced convection of the first fan 130, the second fan 140 and the third fan 150, the first airflow G1, the second airflow G2 and the third airflow G3 of the projection device 200 can cool the projection device 200. Besides, the heat generated by any element of the projection device 200 can be dissipated off the projection device 200 through at least one of the first airflow G1, the second airflow G2, the third airflow G3, the fourth airflow G4 and the fifth airflow G5.

To summarize, the housing of the projection device of the present invention has an air inlet and an air outlet, wherein the air inlet, the air outlet, the projection direction and the direction of gravity are substantially in the same direction. Thus, the air inlet and the air outlet can be exposed from the bottom of the projection device, so that air can be convected between the air inlet and the air outlet and the projection device can project an image downwards (such as a ground, a desktop, a floor or a lower board).

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A projection device configured to project an image in a projection direction, wherein the projection device comprises:
a housing having a first air inlet and a first air outlet, wherein the first air inlet, the first air outlet and the projection direction are in the same direction; and
a projection module disposed inside the housing;
wherein the projection direction and a direction of gravity are in the same direction.

2. The projection device according to claim 1, wherein the projection device is embedded in a recessed portion of a carrier; the first air inlet and the first air outlet are exposed from the recessed portion through which the direction of gravity passes.

3. The projection device according to claim 1, further comprises:
a first fan having a second air inlet which is corresponding to the first air inlet in position; and
a second fan having a second air outlet which is corresponding to the first air outlet in position.

4. The projection device according to claim 3, wherein the first fan is disposed inside the projection module, and the second fan is disposed inside the housing.

5. The projection device according to claim 1, wherein the housing has a lateral plate having the first air outlet, the first air inlet and an opening; the projection module comprises:
a projection lens protruded relative to the opening.

6. The projection device according to claim 1, wherein the first air outlet and the first air inlet are substantially coplanar.

7. The projection device according to claim 1, wherein the projection module is pivotally connected to the housing.

8. The projection device according to claim 7, wherein the projection module further comprises:
a first pivotal element;
wherein the housing comprises a second pivotal element pivotally connected to the first pivotal element.

9. The projection device according to claim 1, wherein the projection module comprises an optical machine; the projection device further comprises:
a third fan disposed adjacent to the optical machine and having the third a third air inlet and a third air outlet, wherein the third air inlet faces the optical machine, and the third air outlet faces the housing.

10. The projection device according to claim 9, wherein the third fan is disposed on the projection module.

11. The projection device according to claim 1, wherein the projection module further comprises:
a casing having a hole; and
a power control unit disposed adjacent to the hole;
wherein the projection device comprises a second fan disposed inside the casing and adjacent to the hole.

12. The projection device according to claim 1, wherein the projection module comprises:
an optical machine; and
a dissipation module disposed adjacent to the optical machine and configured to transfer the heat of the optical machine;
a casing surrounding the optical machine and the dissipation module.

13. The projection device according to claim 1, further comprising:
a second fan having a fourth air inlet;
wherein the projection module further comprises a casing having a hole which is corresponding to the fourth air inlet in position.

14. The projection device according to claim 13, wherein the projection module relatively and rotatably connected to the housing; when the projection module rotates relative to the housing, a movement path of the hole on the casing corresponds to the fourth air inlet.

15. The projection device according to claim 1, wherein the projection module comprises an optical machine, and the projection device further comprises:
a fan disposed inside the optical machine.
